(19) United States
(12) Patent Application Publication
(10) Pub. No.: US 2011/0133732 A1
(43) Pub. Date: Jun. 9, 2011

(54) METHODS AND APPARATUS FOR ENHANCED FREQUENCY RESPONSE OF MAGNETIC SENSORS

(75) Inventor: John B. Sauber, Millbury, MA (US)

(73) Assignee: Allegro Microsystems, Inc., Worcester, MA (US)

(21) Appl. No.: 12/630,362

(22) Filed: Dec. 3, 2009

(51) Int. Cl. G01R 33/06

(52) U.S. Cl. 324/251

(57) ABSTRACT

Methods and apparatus for providing an integrated circuit package device, comprising a conductive leadframe, a magnetic sensor element disposed on the leadframe, wherein the leadframe includes a slot configuration to reduce eddy current flow about the magnetic sensor, the slot configuration including a first slot generally perpendicular to a second slot, wherein the first slot extends under the sensor element.

### BACKGROUND

As is known in the art, magnetic sensors typically include a Hall cell element on the surface of an integrated circuit, which is mounted on a metal leadframe. The sensor is connected to the leadframe with wires and overmolded with thermoset plastic. While such magnetic sensors may be suitable for sensing static magnetic fields, at higher frequencies increasing eddy currents are generated in the conductive leadframe in response to the changing magnetic field. Typical eddy current flow in a circular direction about the leadframe is shown in FIG. 1. Eddy currents flow in circular loops perpendicular to the direction of the magnetic flux vectors. The eddy currents create an opposing magnetic field underneath the Hall cell, which can cause unacceptably large errors in the magnetic field strength detected by the sensor.

While prior art attempts have been made to provide slots in the leadframe to reduce eddy current flow, such slots provide only limited reductions in eddy current levels. U.S. Pat. No. 6,853,178 to Hayat-Dawoodi, for example, shows various slots across the leadframe and crossed slots. However, the '178 slot configurations were found to be inferior to simpler known slot configurations, e.g., a linear slot from the edge of a leadframe.

### SUMMARY

The present invention provides methods and apparatus for a magnetic sensor having a slot configuration in a conductive leadframe that is effective to reduce eddy current flow and provide uniform magnetic field strength across the width of a sensor element, such as a Hall cell. In an exemplary embodiment, the slot configuration includes a first slot and second slot that together form a T-shape. While exemplary embodiments of the inventions are shown and described as having particular geometries, components, and applications, it is understood that embodiments of the invention are applicable to magnetic sensors in general in which it is desirable to reduce eddy current flow.

In one aspect of the invention, an integrated circuit package device comprises a conductive leadframe, and a magnetic sensor element disposed on the leadframe, wherein the leadframe includes a slot configuration to reduce eddy current flow about the magnetic sensor, the slot configuration including a first slot generally perpendicular to a second slot, wherein the first slot extends under the sensor element.

The device can further include one or more of the following features: the second slot is generally parallel to an edge of the sensor element, the first slot extends to an edge of the leadframe, the first slot is longer than the second slot, the second slot is not under the sensor element, a portion of the second slot is under the sensor element, ends of the second slot are rounded, and the device provides a generally uniform magnetic flux intensity over a width of the sensor element.

In another aspect of the invention, a method comprises providing an integrated circuit package device, including: providing a conductive leadframe, and providing a magnetic sensor element disposed on the leadframe, wherein the leadframe includes a slot configuration to reduce eddy current flow about the magnetic sensor, the slot configuration including a first slot generally perpendicular to a second slot, wherein the first slot extends under the sensor element.

The method can further include one or more of the following features: the second slot is generally parallel to an edge of the sensor element, the first slot extends to an edge of the leadframe, the first slot is longer than the second slot, the second slot is not under the sensor element, a portion of the second slot is under the sensor element, ends of the second slot are rounded, and the device provides a generally uniform magnetic flux intensity over a width of the sensor element.

### BRIEF DESCRIPTION OF THE DRAWINGS

The foregoing features of this invention, as well as the invention itself, may be more fully understood from the following description of the drawings in which:

FIG. 1 is a schematic depiction of Eddy current flow in a prior art magnetic sensor;

FIGS. 2A-2D are schematic representations of a magnetic sensor having a slot configuration in a conductive leadframe in accordance with exemplary embodiments of the invention;

FIGS. 2E-G are schematic representations of alternative slot configurations;

FIG. 3 is a schematic depiction of eddy current flow around a magnetic sensor element and slot configuration; and

FIG. 4 is a graphical representation of magnetic flux density for known slot configurations and an inventive slot configuration.

### DETAILED DESCRIPTION

The present invention provides methods and apparatus for eddy current reduction in a magnetic sensor by providing a slot configuration in a leadframe. In an exemplary embodiment, the slot formation includes a first slot and a second slot that combine to form a T-shape. It is understood that the slots are formed through the leadframe so as to prevent the flow of eddy currents. With this arrangement, eddy currents are reduced as compared with prior art slot configurations.

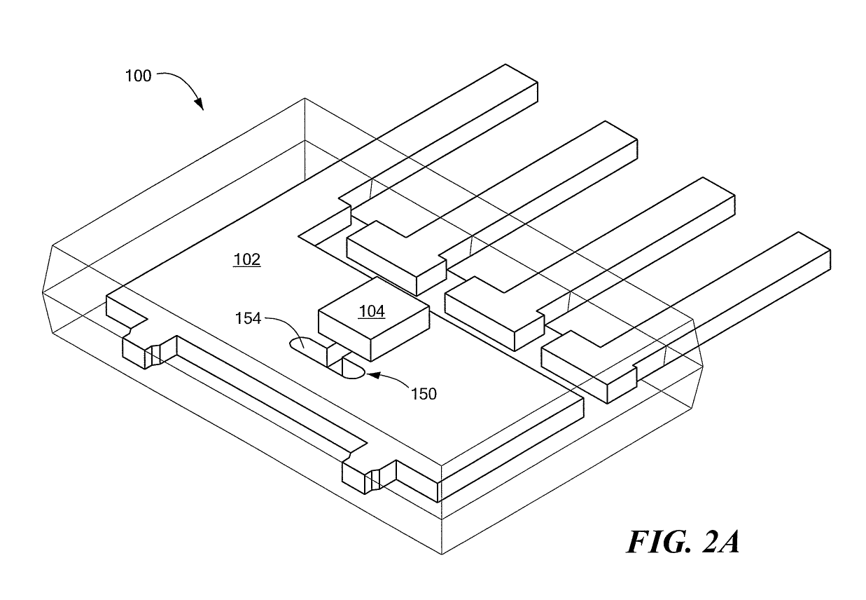

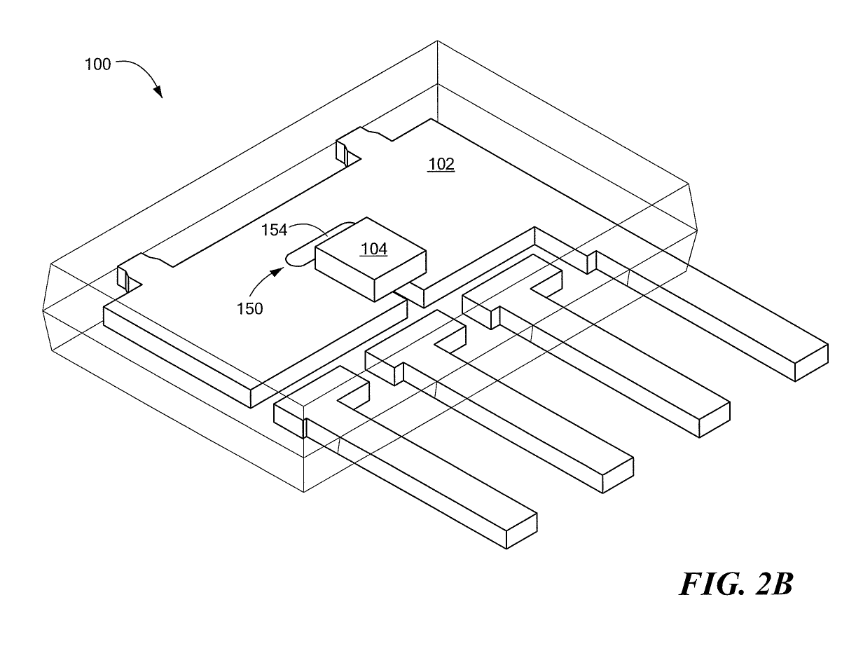

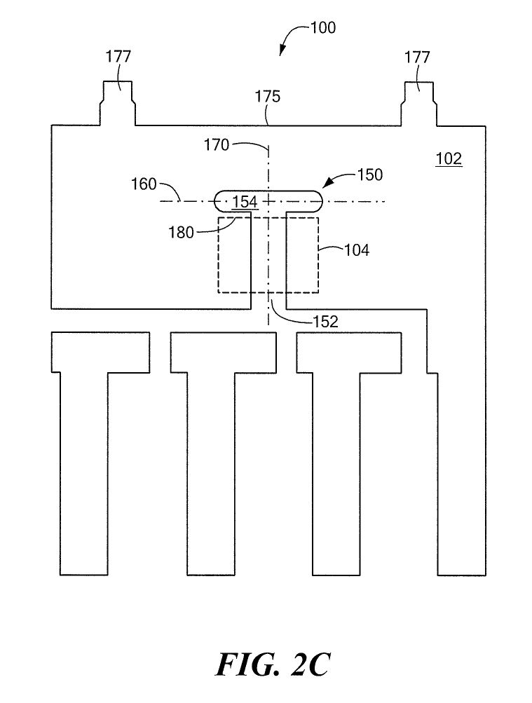

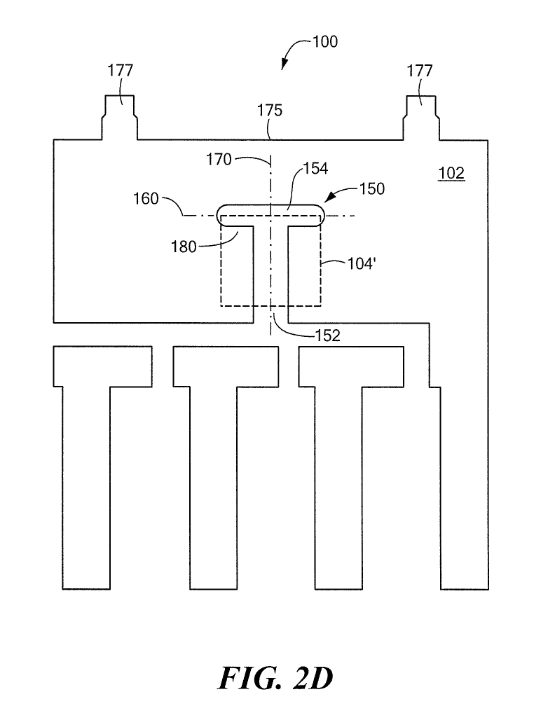

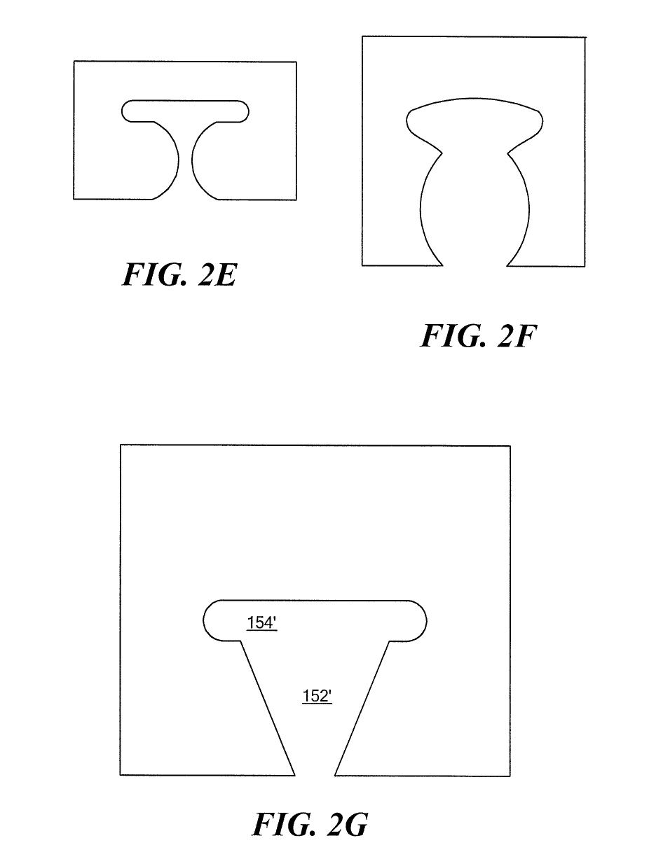

FIGS. 2A-2C show an exemplary magnetic sensor 100 including a conductive leadframe 102 with a magnetic sensor element 104 supported by the leadframe. In one embodiment, the magnetic sensor element 104 is provided as a Hall element. The sensor 104 can be coupled to the leadframe via wires. The assembly can be overmolded with a thermoset plastic or other material to form an integrated circuit package in a manner well known in the art.

The sensor 100 includes a slot configuration 150 to reduce eddy currents flowing about the magnetic sensor element 104. In an exemplary embodiment, the slot configuration 150 includes a first slot 152 and a second slot 154 that together form a generalized ‘T-shape.’ That is, the first slot 152 is generally orthogonal to the second slot 154. It is understood that as used herein, the term “generally orthogonal” means the angle of the second slot 154 with respect to the first slot 152 is ninety degrees plus or minus twenty degrees.

In an exemplary embodiment, the first slot 152 extends under the Hall element 104 to an edge of the leadframe. In one embodiment, a longitudinal axis 170 of the first slot 152 is aligned with a center of the Hall element. In general, the first slot 152 prevents the flow of eddy currents underneath the sensor 104 so as to reduce error.

In one embodiment, a longitudinal axis 160 of the second slot 154 is generally parallel to an edge 180 of the square or rectangular Hall element 104. In the illustrated embodiment, the second slot 154 is not under the Hall element 104. In other embodiments, at least a portion of the second slot 154 is under the Hall element, as shown in FIG. 2D. In exemplary embodiments, ends of the second slot 154 are rounded to eliminate corners.

While the first and second slots are shown as having linear sides, it is understood that the slots can be defined by arcuate sides also. That is, the slots can include concave and convex curvatures, as shown in FIGS. 2E and 2F.

In addition, in further embodiments, the first and/or second slot can change in width. For example, in the embodiment illustrated in FIG. 2G, the first slot 152′ can widen as it transitions into the second slot.

It is understood that certain structural limitations may need to be met to maintain the structural integrity of a device. In one particular embodiment, the first slot 152 has a maximum width of about 12 mils to enable a GaAs Hall element to be secured on the leadframe while straddling the first slot 152. In addition, there may be a tradeoff in the location of the second slot 154. For example, it may be desirable to place the second slot 154 further up (a longer first slot 152) the leadframe to keep eddy currents away from the Hall cell, however, mechanical processing of the assembly limits placement of the second slot to a predetermined distance from a far edge 175 of the leadframe. This distance from the edge 175 may be required to maintain structural integrity when the tie bars 177 on the leadframe are removed during the singulation process, for example.

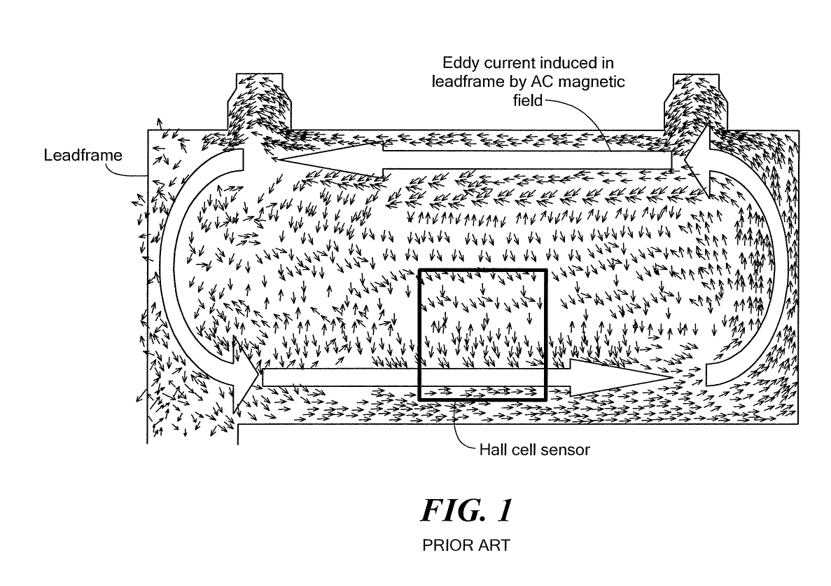

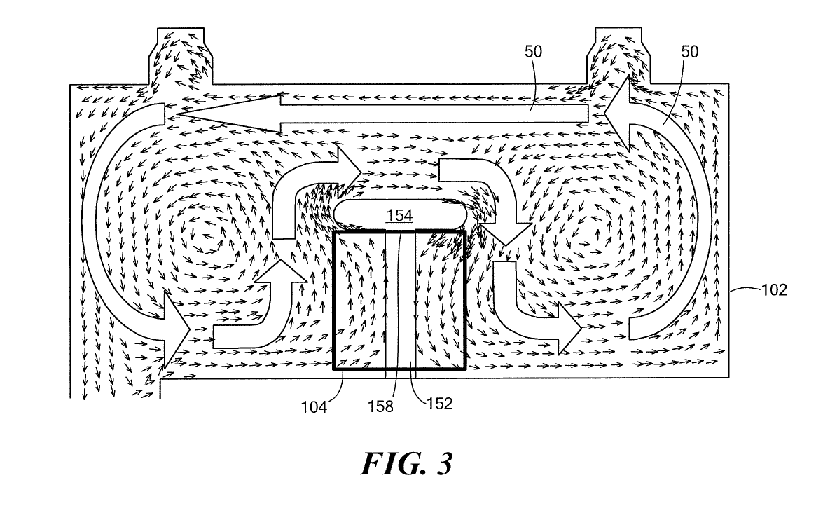

As shown in FIG. 3, the slot configuration 150 interrupts the circular path around the perimeter of the leadframe 102 (see FIG. 1), and forces the eddy currents 50 to flow over the top edge 158 of the sensor 104 rather than around the whole sensor in a circular path. This significantly reduces the opposing magnetic field caused by the eddy currents 50, and thereby significantly reduces sensor output error at high frequencies, e.g., the prior art configuration of FIG. 1 produces errors greater than 10% at frequencies as low as 1 kHz.

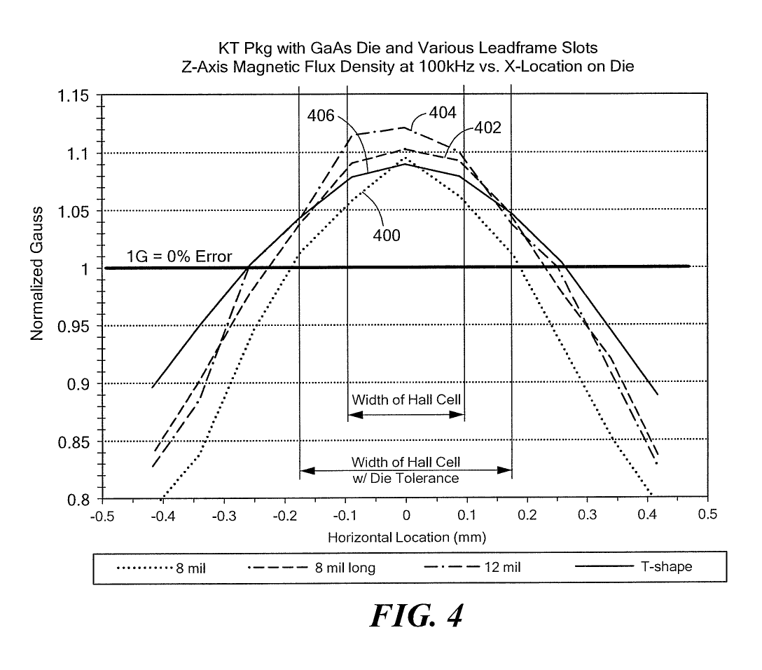

FIG. 4 shows a graphical comparison of magnetic flux density acting on a magnetic sensor for a series of different slot configurations. A first plot 400 of flux density is for a linear slot 8 mils wide. A second plot 402 is for a linear slot 8 mils wide and longer than the slot of the first plot. A third plot 404 is a for a linear slot 12 mils wide. A fourth plot 406 is for a T-shaped slot in accordance with exemplary embodiments of the invention.

It can be seen that errors in the magnetic field strength across the Hall cell are lowest for the T-slot design 406 and for the first 8-mil wide slot design 400. Although the errors may be slightly lower for the first 8-mil design 400 than T-shape 406, there is more of a range, which produces more parametric scatter given a random sensor location distribution. In addition, for the first 8-mil slot 400 there is significantly more of a magnetic flux gradient across the Hall cell as compared to the inventive ‘T-shape’ slot configuration 406. As will be readily appreciated, the gradient decreases accuracy of the sensor output. For at least these reasons, it is readily apparent that the inventive ‘T-shape’ slot configurations are superior to the linear slot configurations.

In an exemplary embodiment, the first slot is about 8 mils in width and about 43 mils in length and the second slot is about 8 mils in width and 35 mils in length. The slots can be as narrow as the leadframe fabrication technology (stamping or etching) allows. The slots must be long enough to prevent the eddy currents from circulating under the die, but short enough so as to not compromise the structural integrity of the leadframe. In an exemplary embodiment, a desired trade-off is determined by an electromagnetic analysis to determine the error from the eddy currents, and a structural analysis to verify that the strength of the assembly is sufficient for processing and end-use requirements.

It is understood that any suitable magnetic sensor element that detects the magnetic field perpendicular to the sensor can be used for the device. Exemplary elements include Hall cells, GaAs cells, and the like.

Having described exemplary embodiments of the invention, it will now become apparent to one of ordinary skill in the art that other embodiments incorporating their concepts may also be used. The embodiments contained herein should not be limited to disclosed embodiments but rather should be limited only by the spirit and scope of the appended claims. All publications and references cited herein are expressly incorporated herein by reference in their entirety.

What is claimed is:

1. An integrated circuit package device, comprising:
a conductive leadframe; and
a magnetic sensor element disposed on the leadframe;
wherein the leadframe includes a slot configuration to reduce eddy current flow about the magnetic sensor, the slot configuration including a first slot generally perpendicular to a second slot, wherein the first slot extends under the sensor element.

2. The device according to claim 1, wherein the second slot is generally parallel to an edge of the sensor element.

3. The device according to claim 1, wherein the first slot extends to an edge of the leadframe.

4. The device according to claim 1, wherein the first slot is longer than the second slot.

5. The device according to claim 1, wherein the second slot is not under the sensor element.

6. The device according to claim 1, wherein a portion of the second slot is under the sensor element.

7. The device according to claim 1, wherein ends of the second slot are rounded.

8. The device according to claim 1, wherein the device provides a generally uniform magnetic flux intensity over a width of the sensor element.

9. A method, comprising:
providing an integrated circuit package device, including:
providing a conductive leadframe; and
providing a magnetic sensor element disposed on the leadframe;
wherein the leadframe includes a slot configuration to reduce eddy current flow about the magnetic sensor, the slot configuration including a first slot generally perpendicular to a second slot, wherein the first slot extends under the sensor element.

10. The method according to claim 9, wherein the second slot is generally parallel to an edge of the sensor element.

11. The method according to claim 9, wherein the first slot extends to an edge of the leadframe.

12. The method according to claim 9, wherein the first slot is longer than the second slot.

13. The method according to claim 9, wherein the second slot is not under the sensor element.

14. The method according to claim 9, wherein a portion of the second slot is under the sensor element.

15. The method according to claim 9, wherein ends of the second slot are rounded.

16. The method according to claim 9, wherein the device provides a generally uniform magnetic flux intensity over a width of the sensor element.
